(19) United States
(12) Patent Application Publication
(10) Pub. No.: US 2014/0327034 A1
(43) Pub. Date: Nov. 6, 2014

(54) SEMICONDUCTOR LIGHT EMITTING DEVICE AND METHOD OF MANUFACTURING THE SAME

(71) Applicant: DOWA ELECTRONICS MATERIALS CO., LTD., Tokyo (JP)

(72) Inventor: Tatsunori Toyota, Akita-shi (JP)

(21) Appl. No.: 14/357,998

(22) PCT Filed: Nov. 6, 2012
(86) PCT No.: PCT/JP2012/079196

§ 371 Date: May 13, 2014

(30) Foreign Application Priority Data
Nov. 14, 2011 (JP) 2011-249141

(51) Int. Cl. H01L 33/38; H01L 33/30; H01L 33/00

(52) U.S. Cl. CPC H01L 33/38; H01L 33/0075; H01L 33/30
USPC 257/99; 438/26

(57) ABSTRACT

A semiconductor light emitting device of the present invention includes a semiconductor laminate including a first conductivity type semiconductor layer, a light emitting layer, and a second conductivity-type semiconductor layer in his order; a contact portion including a stack including a contact layer and an ohmic electrode layer on the first conductivity type semiconductor layer; a first electrode which is in contact with the ohmic electrode layer and is electrically connected to the first conductivity-type semiconductor layer; a second electrode electrically connected to the second conductivity type semiconductor layer. The contact portion has a plurality of island-like openings in which the first conductivity-type semiconductor layer is exposed.

### TECHNICAL FIELD

The present invention relates to a semiconductor light emitting device and a method for manufacturing the same. The present invention relates in particular to a semiconductor light emitting device with improved light output power achieved without significantly increasing forward voltage and a method for manufacturing the same.

### BACKGROUND ART

In recent years, ultraviolet light emitting diodes (LEDs) which emit light in an ultraviolet light region, particularly having an emission wavelength of less than 350 nm, and even deep ultraviolet LEDs having an emission wavelength of 300 nm or less have attracted attention as LEDs that can be used in the fields of sterilization, water purification, medical treatment, illumination, high-density optical recording, and the like.

Some of such LEDs emitting ultraviolet light are known to have a device structure formed using an AlGaN-based thin film which is a III nitride semiconductor, or a diamond thin film as a device material. An example is a semiconductor light emitting device having a light emitting layer; a semiconductor laminate including a p-type semiconductor layer and an n-type semiconductor layer with the light emitting layer interposed therebetween; a p-side electrode on the p-type semiconductor layer side; and an n-side electrode on the n-type semiconductor layer side.

As such a semiconductor light emitting device, JP 2005-259970 A (PTL 1) describes a semiconductor light emitting device having improved adhesion between a p-type contact layer and a positive electrode, increased contact surface area, and reduced operation voltage, which semiconductor light emitting device being obtained by providing irregularities on a surface of the p-type contact layer, and forming the positive electrode made of an ITO film on the substantially entire surface including the irregularities.

### CITATION LIST

### Patent Literature

PTL 1: JP 2005-259970 A

### SUMMARY OF INVENTION

### Technical Problem

The properties of a semiconductor light emitting device include for example light output power and forward voltage. It is important to improve these properties in a balanced manner.

For a semiconductor light emitting device, for example when a p-side electrode is directly formed on a p-type semiconductor layer, the contact resistance therebetween is high, which makes it impossible to obtain good ohmic contact. Therefore, a low resistance p-type contact layer having lower contact resistance with respect to the p-side electrode is usually provided between the p-type semiconductor layer and the p-side electrode. As for an example of an LED emitting a light having a wavelength in an ultraviolet light region or a blue light region, when an AlGaN-based thin film that is a III-nitride semiconductor is used for a semiconductor laminate, a higher Al composition ratio of the AlGaN thin film leads to higher resistance in p-type conduction. As such, since it is currently difficult to obtain a practical high Al content p-type contact layer, in order to lower the forward voltage, use of an AlGaN layer having a low Al composition ratio or a GaN layer free of Al as a p-type contact layer is unavoidable.

However, in the attempt of the inventors of the present invention to develop a light emitting device including a light emitting layer having a high Al content and having a wide band gap, it was found that as the Al content of a p-type contact layer is lower than an AlGaN layer of the light emitting layer, the band gap of the p-type contact layer becomes lower, which facilitate absorption of light emitted from the light emitting layer into the p-type contact layer. Accordingly, when a p-type contact layer such as GaN is provided on the entire surface of the p-type semiconductor layer, it was found that although a good ohmic contact can be obtained between the p-type semiconductor layer and the p-side electrode to achieve a low forward voltage, the p-type contact layer absorbs light, which makes it impossible to obtain high light output power. Thus, it is significantly difficult to improve light emission efficiency of a light emitting device while achieving both low forward voltage and high light output power, which has been a problem.

Further, ohmic electrode layers which can form a good ohmic contact with a p-type contact layer, for example, a metal electrode of Ni/Au or the like and an electrode of ITO or the like however have a low transmittance with respect to ultraviolet light and absorb ultraviolet light. These electrodes have a relatively high transmittance with respect to visible light such as blue light, so that they can be used as a whole surface electrode in a light emitting device emitting blue light as in PTL 1. However, there were no findings on using these ohmic electrode layers in a semiconductor light emitting device emitting ultraviolet light in the same form as in a visible light emitting device. According to the studies made by the inventors of the present invention, it was found that ultraviolet light is absorbed in a semiconductor light emitting device emitting ultraviolet light, which significantly reduces the light output power.

Such a problem also applies to an n-type semiconductor layer and an n-side electrode.

In view of the above problem, it is an object of the present invention to provide a semiconductor light emitting device capable of improving light output power without particularly increasing the forward voltage by attempts to achieve both suppression of light absorption in a contact portion including a contact layer and an ohmic electrode layer and a good ohmic contact between the electrode and a semiconductor layer; and to provide a method of producing the same.

### Solution to Problem

Taking the above problems into consideration, the primary features of the present invention are as follows.

(1) A semiconductor light emitting device comprising:

a semiconductor laminate including a first conductivity type semiconductor layer, a light emitting layer, and a second conductivity type semiconductor layer having

a conductivity type different from the first conductivity type, in this order;

a contact portion in which a contact layer and an ohmic electrode layer are stacked on the first conductivity type semiconductor layer;

a plurality of island-like openings provided in the contact portion, in which openings the first conductivity type semiconductor layer is exposed;

a first electrode which is in contact with the ohmic electrode layer and is electrically connected to the first conductivity type semiconductor layer; and

a second electrode electrically connected to the second conductivity type semiconductor layer.

(2) The semiconductor light emitting device according to (1) above, wherein the shape of the plurality of the openings is non-uniform viewed from above the device.
(3) The semiconductor light emitting device according to (1) or (2) above, wherein the band gap of the contact layer is narrower than the band gap of the light emitting layer.
(4) The semiconductor light emitting device according to (3) above, wherein the semiconductor laminate is made of a III-nitride semiconductor, and the contact layer is made of AlₓGa₁₋ₓN (0≦x<0.5).
(5) The semiconductor light emitting device according to any one of (1) to (4) above, wherein the light emitting layer emits ultraviolet light.
(6) The semiconductor light emitting device according to any one of (1) to (5) above, wherein the first conductivity type semiconductor layer is a p-type semiconductor layer.
(7) A method of manufacturing a semiconductor light emitting device, comprising the steps of:

forming a semiconductor laminate including a second conductivity type semiconductor layer, a light emitting layer, and a first conductivity type semiconductor layer having a conductivity type different from the second conductivity type, in this order, on a substrate;

forming a contact portion in which a contact layer and an ohmic electrode layer are stacked on the first conductivity type semiconductor layer;

forming a mask on part of the contact portion;

removing part of the contact portion which is exposed without being provided with the mask by etching, thereby forming a plurality of island-like openings in the contact portion such that the first conductivity type semiconductor layer is exposed;

forming a first electrode which is in contact with the ohmic electrode layer and is electrically connected to the first conductivity type semiconductor layer; and

forming a second electrode electrically connected to the second conductivity type semiconductor layer.

(8) The method of manufacturing a semiconductor light emitting device, according to (7) above, wherein the shape of the plurality of the openings is non-uniform viewed from above the device.
(9) The method of manufacturing a semiconductor light emitting device, according to (7) or (8) above, wherein the step of forming the mask comprises the steps of:

forming an aluminum oxide film on the contact portion by aluminum deposition in an oxygen atmosphere; and

partially etching the aluminum oxide film.

(10) The method of manufacturing a semiconductor light emitting device, according to any one of (7) to (9) above, wherein the light emitting layer emits ultraviolet light.

### Advantageous Effect of Invention

According to the present invention, openings are provided in a contact portion in which a contact layer and an ohmic electrode layer of a semiconductor light emitting device are stacked, which allows attempts to achieve both suppression of light absorption in the contact portion and a good ohmic contact between the electrode and a semiconductor layer. Thus, the light output power can be improved without significantly increasing forward voltage.

### BRIEF DESCRIPTION OF DRAWINGS

FIG. 1 is a schematic cross-sectional view showing a semiconductor light emitting device 100 according to the present invention.

FIG. 2 is a schematic top view of a semiconductor light emitting device 100 shown in FIG. 1.

FIGS. 3(A) to 3(H) are schematic cross-sectional views showing examples of a method of manufacturing a semiconductor light emitting device 100 according to the present invention.

FIG. 4 is a schematic cross-sectional view showing a semiconductor light emitting device 100 obtained by flip-chip type mounting.

FIGS. 5(A) and 5(B) are SEM images of a top surface of a contact portion in Example 1 and Example 2, respectively.

FIG. 6 is an enlarged SEM image of FIG. 5(A).

FIG. 7 is a SEM image of a contact portion in Example 3.

FIG. 8 is an enlarged SEM image of a contact portion in Example 4.

### DESCRIPTION OF EMBODIMENTS

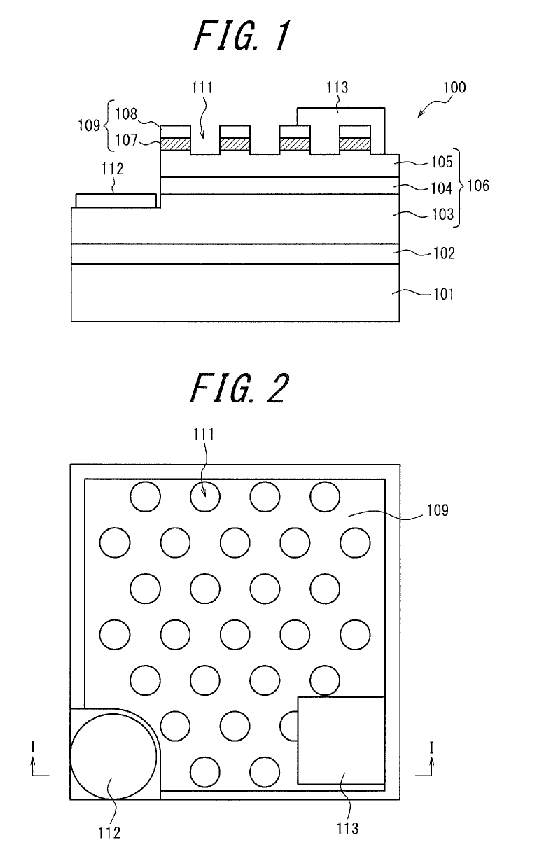

The present invention will be described in more detail, with reference to the accompanying drawings. Note that, in the schematic cross-sectional views of light emitting devices, each layer is enlarged for the sake of explanation; accordingly, the ratio of the illustrated layers to the illustrated substrate does not conform to the actual ratio. FIG. 1 shows a cross section along I-I in FIG. 2.

A semiconductor light emitting device 100 which is an embodiment of the present invention has a buffer layer 102; a semiconductor laminate 106; and a contact portion 109 in which a contact layer 107 and an ohmic electrode layer 108 are stacked, in this order on a substrate 101 as shown in FIG. 1

The semiconductor laminate 106 includes a p-type semiconductor layer 105 as a first conductivity type semiconductor layer; a light emitting layer 104; and an n-type semiconductor layer 103 as a second conductivity type semiconductor layer having a conductivity type different from the first conductivity type. In this embodiment, the n-type semiconductor layer 103, the light emitting layer 104, and the p-type semiconductor layer 105 are formed in this order from the buffer layer 102 side.

The p-type electrode 113 as a first electrode is located on the contact portion 109, more specifically, on a part of the ohmic electrode layer 108 as shown in FIG. 1 and FIG. 2, and the p-type electrode 113 is in contact with the ohmic electrode layer 108 and electrically connected to the p-type semiconductor layer 105 via the contact portion 109. The n-side electrode 112 as a second electrode is formed on the n-type semiconductor layer 103 side of the semiconductor laminate 106. The n-side electrode 112 is electrically connected to the n-type semiconductor layer 103. For an example, FIG. 1 schematically shows a typical “lateral” light emitting device in which the contact portion 109 and the semiconductor laminate 106 are removed in a region of the semiconductor light emitting device 100 to expose a surface of the n-type semiconductor layer 103, thereby providing the n-type electrode 112 on the exposed n-type semiconductor layer 103.

A substrate used as the substrate 101 is preferably resistant to the temperature of epitaxial growth of the semiconductor laminate 106. For example, a sapphire substrate or an AlN template in which an AlN single crystal layer is formed on a substrate made of sapphire or the like can be used.

The buffer layer 102 is epitaxially grown on the substrate 101 by a known technique such as MOCVD, MOVPE, HVPE, or MBE. For example, a laminate made of an AlN layer or a plurality of AlGaN layers, which have a thickness of 20 nm to 1500 nm, preferably 500 nm to 1500 nm, more preferably 800 nm to 1000 nm. The buffer layer 102 serves as a strain buffer layer for preventing strains between the substrate 101 and the n-type semiconductor layer 103. Further, the buffer layer 102 may include a composition graded layer or a superlattice strain buffer layer.

The n-type semiconductor layer 103 and the p-type semiconductor layer 105 can be formed by epitaxially growing AlₓGa₁₋ₓN material (0<x≦1) by a known technique such as MOCVD. Unless absorption of light at the desired emission wavelength causes a problem, they may contain B or In as a Group III element, and As as a Group V element. P-type impurities can be exemplified by Be and Mg, whereas n-type impurities can be exemplified by Si and Ge.

The light emitting layer 104 may have, for example, a multiple quantum-well structure of AlInGaN/AlInGaN. This can be formed by growth using MOCVD or the like. The light emitting layer 104 can be made of a material having a relatively wide band gap, and capable of emitting ultraviolet light having a center emission wavelength of 380 nm or less or visible light (blue, violet) having a center emission wavelength of 495 nm or less, and the like. The light emitting layer 104 emitting ultraviolet light can be, for example, a light emitting layer emitting ultraviolet light having a center emission wavelength of 380 nm or less, which layer having a transmittance of 50% or less with respect to the center emission wavelength due to the absorption caused when the light is transmitted through the GaN (x=0) layer; can be a light emitting layer emitting ultraviolet light having a center emission wavelength of 365 nm or less which is not substantially transmitted through the GaN layer; or even can be a light emitting layer emitting ultraviolet light having a center emission wavelength of 350 nm or less. Note that for the multiple quantum-well structure of AlInGaN/AlInGaN, the emission wavelength can be controlled mainly with the Al composition ratio of the well layer.

For the thickness of each layer, for example, the n-type semiconductor layer 103 can be 1000 nm to 5000 nm, the light emitting layer 104 can be 10 nm to 100 nm, and the p-type semiconductor layer 105 can be 50 nm to 300 nm.

Here, the contact portion 109 will be described.

First, the p-type contact layer 107 is epitaxially grown on the p-type semiconductor layer 105. The contact layer 107 is a layer having reduced p-type conductivity and a lower contact resistance with respect to the p-side electrode 113 than the p-type semiconductor layer 105. Further, the contact layer is well lattice matched to the p-type semiconductor layer 105, and preferably has a lattice constant allowing it to be epitaxially grown on the p-type semiconductor layer 105.

When the band gap of the contact layer 107 is narrower than the band gap of the light emitting layer 104, the advantageous effect of the present invention is significant. This is because the problem of absorption of the light emitted from the light emitting layer 104 into the contact layer 107 is caused significantly in that case.

When the semiconductor laminate 106 is made of, for example, a III-nitride semiconductor, the advantageous effect of the present invention is significant where the Al composition of the contact layer 107 is such that the band gap thereof is narrower than the band gap of the light emitting layer, or the transmittance thereof with respect to the center emission wavelength of the light from the light emitting layer is less than 50%. When the Al composition of the contact layer 107 has a composition formula of AlₓGa₁₋ₓN, for example, 0≦x<0.5 is preferable and 0≦x≦0.05 is more preferable although depending on the emission wavelength. In that case, since the contact layer 107 has a low Al content or no Al, it is well lattice matched to the p-type semiconductor layer 105. Further, the contact resistance of the contact layer 107 with respect to the p-side electrode 113 is sufficiently lower than the p-type semiconductor layer 105. Accordingly, x<0.5 is preferable because the carrier density does not significantly reduced, whereas x≦0.05 is more preferable because low contact resistance can be obtained as with the case of GaN. Note that for a light emitting layer emitting ultraviolet light having a center emission wavelength of 350 nm or less, the light is greatly absorbed into the contact layer even if the contact layer satisfies x=0.05. Further, the contact layer may contain a little amount of another congener such as In.

Next, the p-side ohmic electrode layer 108 is formed on the p-type contact layer 107. The ohmic electrode layer 108 is a low contact resistance layer suitable for forming an ohmic contact with the p-type contact layer 107. For example, the ohmic electrode layer is preferably obtained by the combination of a metal such as Ni, Co, ITO, or Pt and a metal such as Au or Rh. Further, the p-side ohmic electrode layer 108 necessarily can be metal-joined to the p-side electrode 113.

Both the contact layer 107 and the ohmic electrode layer 108 included in the contact portion 109 absorb light produced in the light emitting layer 104. Note that the contact portion 109 may absorb part of the light and transmit or reflect other part thereof; however, the advantageous effect of the present invention can easily be achieved when it absorbs 50% or more of the center emission wavelength.

Here, for a characteristic structure of the present invention, as shown in FIG. 1 and FIG. 2, the contact portion 109 has island-like openings 111 in which the p-type semiconductor layer 105 is exposed. In the openings 111 on the p-type semiconductor layer 105, the light produced in the light emitting layer 104 is not absorbed by the contact layer 107 and the ohmic electrode layer 108 that form the contact portion 109. Accordingly, the light can be effectively extracted outside through the openings 111. On the other hand, in a region where the contact portion 109 is formed on the p-type semiconductor layer 105, a good ohmic contact can be obtained between the p-type semiconductor layer 105 and the p-side electrode 113 via the ohmic electrode layer 108 and the contact layer 107. Thus, in the present invention, the provision of the openings 111 in the contact portion 109 allows suppression of light absorption by the contact portion and a good ohmic contact between the electrode and the semiconductor layer. Thus, the light emission efficiency can be improved without significantly increasing forward voltage.

Further, the present invention has a structure in which island-like, or isolated openings 111 exist in the contact portion 109, which may result in the state where the whole contact portion 109 is electrically connected to the p-side electrode 113 without forming isolated contact portions as shown in FIG. 2. Accordingly, a current can be sufficiently flown not only to the semiconductor laminate immediately under the p-side electrode 113, but also to the region where the contact portion 109 is provided and to the semiconductor laminate in the vicinity thereof and underneath thereof. This leads to the improvement of light emission efficiency.

The location of the p-side electrode 113 is not particularly limited to FIG. 2 as long as the p-side electrode 113 is in contact with a part of the ohmic electrode layer 108 of the contact portion 109.

The present invention is effective when the first conductivity type semiconductor layer, that is, the semiconductor layer exposed in the openings is a p-type semiconductor layer as in this embodiment. Since a current does not spread easier inside the p-type semiconductor layer 105 as compared with an n-type semiconductor layer, the contact portion 109 is preferably extended not only immediately under the p-side electrode 113, but also as widely as possible on the p-type semiconductor layer 105. The contact portion 109 is formed on the entire surface of the p-type semiconductor layer 105 and openings 111 are formed in part of it, which allows light to be emitted from a larger area and the light emission efficiency to be increased.

Further, when the semiconductor layer exposed in the openings is a p-type semiconductor layer, it is preferable that the plurality of openings 111 are dispersed on the p-type semiconductor layer 105, specifically, when viewed from above the device, the openings 111 are distributed to be dispersed over the entire surface as shown in FIG. 2. As a result, the contact portion 109 is also laid all over the p-type semiconductor layer 105 accordingly, so that the current supplied from the p-side electrode 113 can be supplied to the whole p-type semiconductor layer 105.

The arrangement pattern of the openings 111 in the contact portion 109 viewed from above the device is not limited in particular. They can be formed in a regular pattern as illustrated in the schematic view of FIG. 2 or in a random pattern as in FIG. 5.

The shape of the openings viewed from above the device is not limited in particular, yet the shape of the plurality of openings is preferably non-uniform, specifically, varying without regularity as in FIG. 5. Since the p-type semiconductor layer 105 partially serves as a side surface of the openings 111 in the lower part of the contact portion 109, when the openings 111 have non-uniform shapes, the same exposed area of the p-type semiconductor layer 105 viewed from above (the same aperture ratio) means an increased total exposed area of the p-type semiconductor layer 105, including the area of the side surface of the openings. Thus, the efficiency of light extraction through the opening 111 is improved.

Here, in terms of achieving both a good ohmic contact and high light extraction efficiency, when the area of the p-type semiconductor layer 105 provided with the contact portion 109 is expressed as S1 and the sum total area of the openings 111 is expressed as S2, the aperture ratio (S2/(S1+S2)) is preferably in the range of 0.05 to 0.65, more preferably in the range of 0.2 to 0.4. An aperture ratio of 0.05 or more ensures the effect of improving light extraction due to the openings, whereas a ratio of the openings of 0.65 or less would cause less discontinuity in the contact portion 111. Thus, a sufficient ohmic contact can be obtained.

For the n-side electrode 112, for example, a Ti/Al electrode obtained by sequentially vapor-depositing a Ti-containing film and an Al-containing film by vacuum deposition can be used for the reason that it has low contact resistance with respect to the n-type semiconductor 103. For the p-side electrode 113, for example, a Ni/Au electrode obtained by sequentially vapor depositing a Ni-containing film and a Au-containing film, and a Ni/Pt electrode can be used for the reason that they have low contact resistance with respect to the p-type semiconductor layer 105.

A III-nitride semiconductor light emitting device 100 has been described, where the first conductivity type is defined as p-type and the second conductivity type is defined as n-type in the present invention; however, the present invention is not limited thereto. Of course, the first conductivity type may be n-type whereas the second conductivity type may be p-type. In that case, metals such as Ti/Al or Mo/Al which forms a relatively good ohmic contact with n-AlGaN which forms the n-type semiconductor layer are preferable as the material of the ohmic electrode layer 108.

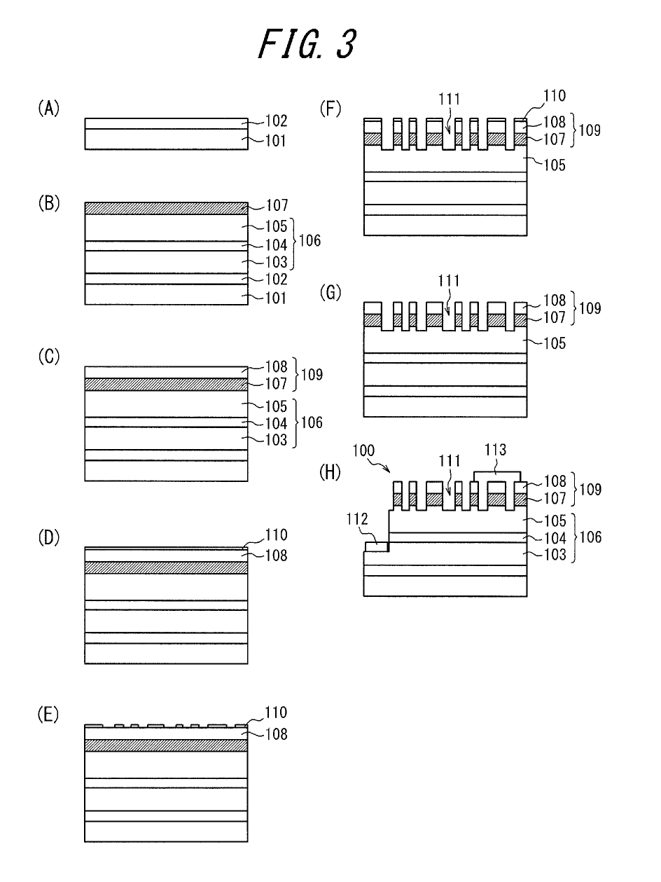

Next, an example of a method for manufacturing a semiconductor light emitting device 100 will be described with reference to FIGS. 3(A) to 3(H). First, as shown in FIG. 3(A), a buffer layer 102 is formed on a substrate 101 for example by MOCVD. Subsequently, as shown in FIG. 3(B), an n-type semiconductor layer 103, a light emitting layer 104, a p-type semiconductor layer 105, and a p-type contact layer 107 is sequentially grown epitaxially on the buffer layer 102, for example by MOCVD, thus forming a semiconductor laminate 106 and the p-type contact layer 107. The n-type semiconductor layer 103 has a second conductivity, and the p-type semiconductor layer 105 has a first conductivity type different from the second conductivity type. Next, as shown in FIG. 3(C), a p-side ohmic electrode layer 108 is stacked on the p-type contact layer 107 to form a contact portion 109. The p-side ohmic electrode layer can be deposited by sputtering, vacuum deposition, or the like. After forming the p-side ohmic electrode layer, an annealing step is preferably performed.

Next, as shown in FIGS. 3(D) and 3(E), a mask 110 is formed on part of the contact portion 109, specifically on part of the ohmic electrode layer 108. First, a layer of a mask material is formed all over (FIG. 3(D)), and this layer is then patterned (FIG. 3(E)). This is to prevent a part under the mask 110 from being etched when the contact layer 107 and the ohmic electrode layer 108 are etched in the next step. The shapes of the contact portion 109 and the openings 111 are determined depending on the shape of the mask 110. Therefore, the mask 110 is formed to have a shape such that the openings having a predetermined or arbitrary shape such as a rectangular or circular shape when viewed from above are located in an irregular or regular manner.

The method of patterning the mask 110 is not limited in particular. A layer of a mask material may be formed on the entire surface of the ohmic electrode 108, a resist pattern is formed on the layer of the mask material by photolithography, and only exposed part of the mask material layer is etched, thus forming a mask having the same pattern as a photomask.

Common techniques using such a photomask are advantageous in that the mask 110 having the desired pattern can be obtained by using a given photomask. The openings are preferably finer because electricity flows easier on the exposed p-type semiconductor layer 105; however, it is difficult to achieve a fine opening shape with a photomask pattern width of 1 μm to 2 μm or less due to design limitations, and the process is complicated.

The inventors of the present invention developed an effective mask formation process without using photolithography. This mask formation process includes a step of forming a metal oxide film 110 on the entire surface of the contact portion 109 by metal deposition in an oxygen atmosphere, and a step of partially etching the metal oxide film 110. For the metal used in this mask formation process, any metal may be used as long as it can be used as a mask for a subsequent etching and the plurality of non-uniform openings can be formed without using any photomasks, yet for example, aluminum is preferable. The inventors of the present invention found that an aluminum oxide film formed by aluminum deposition in an oxygen atmosphere can be partially etched only by being exposed to a wet etching environment without using a photomask, thereby forming the mask 110 having a pattern in which a plurality of finely shaped openings non-uniform in size and shape are dispersed on the ohmic electrode layer 108 (FIG. 3(E)). Fine openings are, for example, openings having a width of 2 μm or less.

An aluminum oxide film formed by aluminum deposition under certain oxygen atmosphere conditions has a non-uniform oxygen concentration in the plane. Conceivably, other than aluminum oxide (Al₂O₃) which can be used as a mask for dry etching, aluminum or an aluminum oxide having a different oxidation number would be partially formed. This can be considered a cause of varied etching properties in the plane. Using a mask fabricated by this method, irregular, fine openings having non-uniform shapes can be formed in a suitably dispersed manner. Note that in the case where the first electrode is formed partially on the contact portion 109, to form the openings in a suitably dispersed manner means to form the openings such that the contact portion 109 can maintain electrical continuity all over the p-type semiconductor layer 105. This is for maintaining the spread of current to suppress the rise of forward voltage due to the openings. When the first electrode is formed on the entire surface of the contact portion 109, the electrical continuity of this contact portion 109 is preferable, but not essential. Further, such a structure is preferred due to the advantages of the controllability of the aperture ratio depending on the conditions for forming the aluminum oxide film or the etching conditions, and the simpler process as compared with methods using a photomask.

The vapor deposition conditions for the aluminum oxide film are not limited in particular as long as the openings can be formed; however, for example, the following conditions may be employed. The flow rate of oxygen is approximately 5 sccm to 15 sccm, whereas the internal pressure of an EB deposition apparatus is approximately 5.0×10⁻³ Pa to 5.0×10⁻² Pa. The film formation may be performed at a deposition rate of 0.5 angstrom/s to 2.0 angstrom/s to a thickness of approximately 500 angstrom to 5000 angstrom.

The etching conditions of the aluminum oxide film are not limited in particular; however, for example, the etching may be performed by immersion in a 63 BHF (Buffered Hydrogen Fluoride) solution for approximately 3 minutes to 10 minutes. Further, a plurality of openings non-uniform in size and shape are formed in the aluminum oxide film. In order to expand the openings, dry etching may be followed. On this occasion, the etching may be performed using CF₄/O₂ as etching gases at a pressure of approximately 1.0 Pa to 4.0 Pa, at flow rates of approximately 10 sccm to 25 sccm/2 sccm to 5 sccm, for an etching time of approximately 0.5 minutes to 3.0 minutes.

After forming the mask 110, as shown in FIG. 3(F), part of the contact portion 109 which is exposed without being provided with the mask 110 is selectively removed by etching, thereby forming the island-like openings 111 in which the p-type semiconductor layer 105 is exposed. For a method of the selective etching, for example, dry etching using a chlorine-based gas or an Ar gas can be used, and the method can be selected depending on the materials of the contact layer 107 and the ohmic electrode layer 108 as appropriate.

As shown in FIG. 3(F), etching is preferably performed such that the p-type semiconductor layer 105 is reduced by, for example approximately 10 nm to 200 nm. Thus, etching removal of the contact layer 107 can be ensured. Further, as a complicated irregular shape is formed on side surfaces of the p-type semiconductor layer 105 in the openings 111, the light entering the p-type semiconductor layer 105 under the contact portion 109 is smoothly extracted due to the irregularities on the side surfaces of the openings 111 that are constituted by the p-type semiconductor layer 105. Thus, the light reflects off the side surfaces, so that little light is absorbed in the contact layer, which results in improved light output power.

After that, the mask 110 is removed by etching (FIG. 3(G)). The mask can be removed for example by etching using hydrogen fluoride.

After that, as shown in FIG. 3(H), the first electrode 113 electrically connected to the p-type semiconductor layer 105 is formed on part of the ohmic electrode layer 108, and the second electrode 112 electrically connected to the n-type semiconductor layer 103 is then formed. The semiconductor laminate 106 is partially removed for example by dry etching or wet etching to expose a surface of the n-type semiconductor layer 103, and the n-side electrode 112 can be formed on the exposed n-type semiconductor layer 103 by sputtering, vacuum deposition, or the like. The p-side electrode 113 can be directly formed on part of the contact portion 109 and the p-type semiconductor layer 105 by sputtering, vacuum deposition, or the like in the like manner.

Thus, the method of manufacturing a lateral semiconductor light emitting device 100 has been described; however, the present invention can also be applied to flip chip semiconductor light emitting devices and vertical semiconductor light emitting devices. An example of the manufacturing methods is described below.

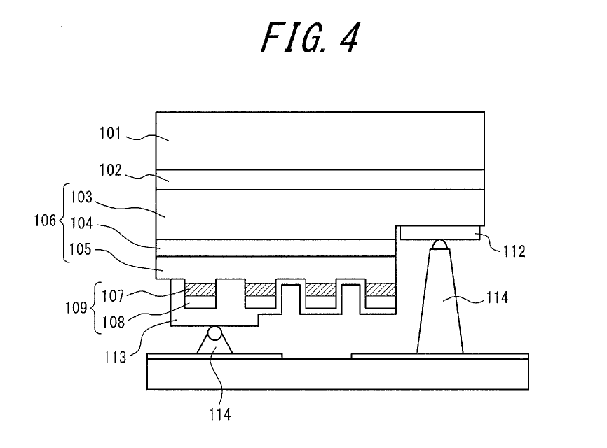

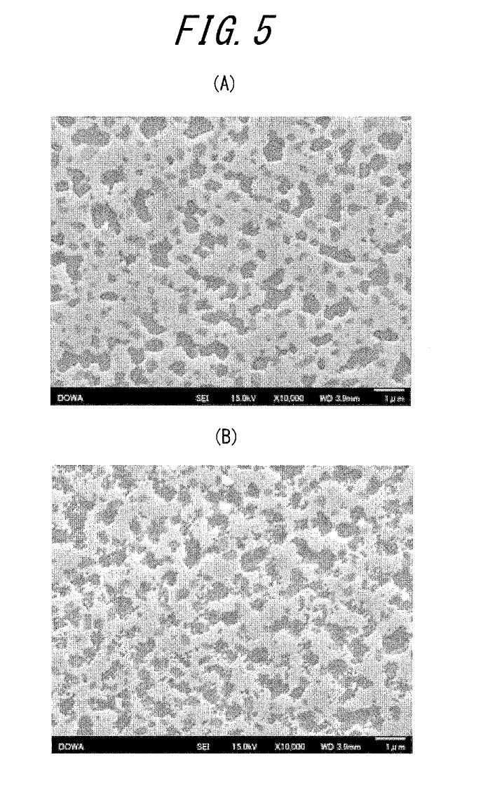

A method of manufacturing a flip-chip semiconductor device includes the same steps up to the formation of the contact portion 109 having the openings 111 as the steps of the manufacturing method according to Embodiment 1 shown in FIGS. 3(A) to 3(G). After those steps, the p-side electrode 113 is directly formed on the entire surface of the contact portion 109 and the p-type semiconductor layer in the openings 111 by sputtering, vacuum deposition, or the like. On this occasion, a highly reflective metal is preferably used for the p-side electrode 113, for example, Mo, Ru, Rh, and W can be used. The semiconductor laminate 106 is partially removed for example by dry etching or wet etching to expose a surface of the n-type semiconductor layer 103, and the n-side electrode 112 can be formed on the exposed n-type semiconductor layer 103 by sputtering, vacuum deposition, or the like. In mounting, bumps 114 are used as shown in FIG. 4. Also in this embodiment, the light delivered to the openings is not absorbed by the contact portion 109 and reflects off the p-side electrode 113, which results in improved light emission efficiency.

In a case of a vertical device, the manufacturing method includes the same steps up to the formation of the contact portion 109 having the openings 111 as the steps of the manufacturing method according to Embodiment 1 shown in FIGS. 3(A) to 3(G) except that a material capable of being lifted off is used for the buffer layer. After those steps, the p-side electrode, a joint metal layer, and a support substrate are sequentially formed on the contact portion 109.

The p-side electrode is formed directly on the entire surface of the contact portion and the p-type semiconductor layer in the openings by sputtering, vacuum deposition, or the like. On this occasion, a highly reflective metal is preferably used for the p-side electrode, for example, Mo, Ru, Rh, and W can be used as a material that reflects ultraviolet light.

When the joint metal layer is coupled to the support substrate by junction, it is preferably made of a Au-containing material, more preferably made of Au or AuSn. When the support substrate is formed by plating, it is preferable to use a material containing Ni, Cu, or any of a noble metal such as Au, Pt, or Pd. Further, a metal resistant to the etchant used to separate the substrate by chemical lift-off is desirably selected as the material. As a barrier layer for stopping the spread of Au from the joint metal layer, a barrier layer made of a Pt-containing material may be additionally formed between the joint metal layer and the p-side electrode.

The support substrate may be made of a material having good heat dissipation properties; for example, a conductive silicon substrate or a substrate made of Mo, W, Ni, or Cu, or an alloy thereof is preferably used. The support substrate may be directly formed by plating as described above; however, in that case, a material resistant to the etchant for subsequent chemical lift-off is preferably selected.

The buffer layer is then removed by etching or the like, thereby separating the substrate from the semiconductor laminate. Subsequently, the n-side electrode is formed on the n-type semiconductor layer having been exposed by the separation. Thus, the vertical semiconductor light emitting device can be manufactured. Note that in the case of the vertical device, it is necessary to remove the buffer layer as described above; therefore, the buffer layer is preferably formed from chromium (Cr), scandium (Sc), hafnium (Hf), zirconium (Zr) or the like or a nitride of such metals, which is a metal material that can be removed by chemical lift-off.

Each of the above embodiments is only an example of exemplary embodiments, and the present invention is not limited to those embodiments. Next, the present invention is described in further detail with Examples, yet the present invention is in no way limited to the following Examples.

### EXAMPLES

### Example 1

An AlN layer was formed as an initial layer by MOCVD on an AlN template having an AlN epitaxial layer on the (0001) plane of a sapphire substrate. Then, an AlN/GaN superlattice layer as a superlattice strain buffer layer, an i-type AlGaN layer, AlGaN as an n-type nitride semiconductor layer (Al composition of contact layer and cladding layer: 0.23), an InAlGaN quantum well structure as a light emitting layer having an emission wavelength of 340 nm (Al composition of well layer: 0.15), and AlGaN as a p-type nitride semiconductor layer (Al composition of blocking layer: 0.47, Al compositions of guide layer and cladding layer: 0.22, thickness of cladding layer: 160 nm) were epitaxially grown sequentially thereon to form a semiconductor laminate. Further, GaN (thickness: 50 nm) was epitaxially grown as a p-type contact layer on the p-type AlGaN cladding layer on the top. Note that the above superlattice strain buffer layer had a structure in which first layers were made of GaN and a superlattice layer I having 20 sets of alternately stacked AlN layers (thickness: 9 nm) and GaN layers (thickness: 2.1 nm), a superlattice layer II having 30 sets of alternately stacked AlN layers (thickness: 2.7 nm) and GaN layers (thickness: 2.1 nm), and a superlattice layer III having 50 sets of alternately stacked AlN layers (thickness: 0.9 nm) and GaN layers (thickness: 2.1 nm) were sequentially stacked. The GaN layers (first layers) were doped with Mg.

A p-side ohmic electrode layer (Ni thickness: 10 nm and Au thickness: 20 nm) was formed on the p-type contact layer by sputtering. After that, heat treatment was performed at 550° C.

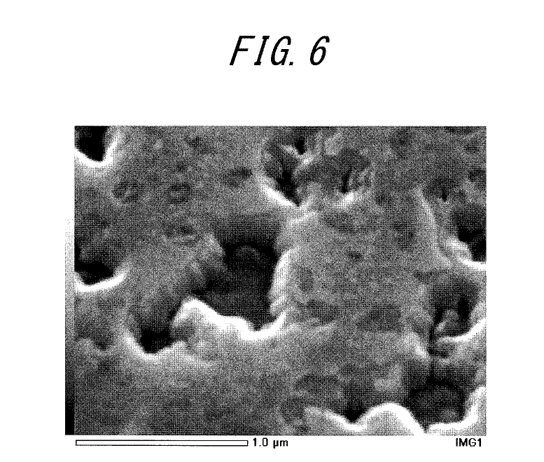

Al was then deposited while introducing an oxygen gas into an EB deposition system after evacuation, thereby depositing an aluminum oxide film (thickness: 200 nm) as a mask material on the p-side ohmic electrode film. Here, the deposition was performed with an oxygen gas at 10 sccm, 1×10⁻² Pa, and 1 angstrom/s. After immersion in BHF for 10 minutes, the aluminum oxide film was partially etched, thus forming a mask having island-like openings in which the p-side ohmic electrode layer is partially exposed. After that, part of the p-side ohmic electrode layer that is not covered with the mask was removed by dry etching using a chlorine gas at a pressure of 1 Pa, at a flow rate of 20 sccm for 3 minutes. Further, part of the p-type contact layer that is not covered with the mask was removed by being exposed to a mixed gas of a chlorine gas at a flow rate of 22.5 sccm and a silicon tetrachloride gas at 7.5 sccm at a pressure of 4 Pa for 1.5 minutes. As a post process, exposure to an argon gas was performed at a pressure of 1 Pa, at a flow rate of 20 sccm for 3.5 minutes. The whole structure was immersed in 45% hydrofluoric acid (HF) for 15 seconds, thereby completely removing the mask of the aluminum oxide film. FIG. 5(A) shows a SEM micrograph of the surface after the mask removal (at 10,000× magnification). Thus, the contact portion having a plurality of island-like openings was formed. The shape of the plurality of openings viewed from above the device was not uniform. Further, a micrograph of the surface magnified (at 50,000× magnification) is shown in FIG. 6. As shown, irregularities were observed on the side surface and at the bottom of the openings having the p-type semiconductor layer. The aperture ratio was calculated from the area ratio of the SEM micrograph to be 30.3%.

The surface of the n-type nitride semiconductor layer was partially exposed by dry etching to form an n-side electrode (Ti/Al) on the n-type nitride semiconductor layer and annealing was performed at 550° C. After that, a p-side electrode (Ti/Au) was formed on the contact portion having the openings. Thus, a semiconductor light emitting device was manufactured.

### Example 2

A semiconductor light emitting device was formed in the same manner as Example 1 except that a step of exposure to a mixed gas of a tetrafluoromethane gas at a flow rate of 21 sccm and an oxygen gas at a flow rate of 4 sccm at a pressure of 4 Pa for 2.5 minutes is added after forming a mask having island-like openings in which the p-side ohmic electrode layer is partially exposed. FIG. 5(B) shows a SEM micrograph of the surface after the mask removal (at 10,000× magnification). The shape of the plurality of openings viewed from above the device was not uniform. The above treatment expanded the openings of the mask, and the aperture ratio was calculated from the area ratio of the SEM micrograph to be 38.3%. Further, the openings including the p-type semiconductor layer were observed, and irregularities similar to the ones observed in Example 1 were found.

### Example 3

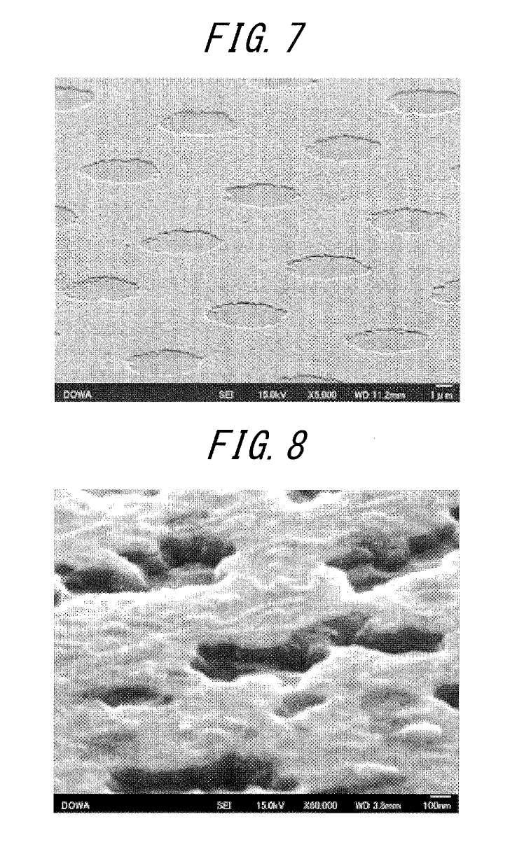

In the procedure of Example 1, after performing the heat treatment after the formation of the p-side ohmic electrode layer, a SiO₂ film was deposited by CVD as a mask material on the p-side ohmic electrode film instead of the aluminum oxide film, and a photo resist pattern was formed which has a plurality of openings having a diameter of 5 μm at a center-to-center interval of 10 μm on the SiO₂ film by photolithography. After that, the SiO₂ film was etched by dry etching using the resist pattern as a mask, and the resist was removed. The thus formed SiO₂ film pattern was used as the mask having a plurality of island-like openings to etch the p-side ohmic electrode and the p-contact mask layer by the same dry etching as Example 1. Subsequently, the SiO₂ mask was removed by immersion in BHF. A SEM micrograph (at 50,000× magnification) of the surface after the mask removal is shown in FIG. 7. After that, the semiconductor light emitting device was formed in the like manner as Example 1. As a result, openings having a shape corresponding to the pattern of the photomask were formed in the contact portion were formed; specifically, openings having a diameter of 5 were uniformly formed at a pitch of 10 μm. The aperture ratio of the photomask was 19% in design, whereas that of the contact portion was calculated from the area ratio of the SEM micrograph to be 20%.

### Example 4

Example 4 was performed in the same manner as Example 1 except that the aluminum oxide film (thickness: 200 nm) having been deposited as the mask material on the p-side ohmic electrode film was immersed for a period of 6 minutes instead of 10 minutes. A micrograph of the contact portion magnified (at 50,000× magnification) is shown in FIG. 8. The shape of the plurality of openings was not uniform. The aperture ratio was calculated from the area ratio of the SEM micrograph to be 20%. Note that the shape of the plurality of the openings viewed from above the device was similar to that in Example 1, whereas the same aperture ratio as Example 3 was obtained although the shape of the openings was different from that in Example 3.

### Example 5

Example 5 was performed in the same manner as Example 1 except that after completely removing the mask of the aluminum oxide film, a reflective electrode (Ru, thickness: 50 nm) was formed by sputtering to cover the entire surface of the openings and the contact portion, and a p-side electrode (Ti/Au) was formed on the above reflective electrode.

### Example 6

A semiconductor light emitting device was formed in the same manner as Example 2 except that an InGaN quantum well structure having an emission wavelength of 465 nm was used as a light emitting layer.

### Comparative Examples 1 to 6

Semiconductor light emitting devices were formed in the same manner as Examples 1 to 6, respectively, except that the mask was not formed and the openings of the contact portion were not formed by dry etching.

### (Evaluation Method)

The light output power Po and the forward voltage Vf were measured while flowing a current of 20 mA, 50 mA, or 100 mA to the obtained light emitting devices using a constant current voltage power supply. In Table 1, the Po ratios of Examples 1 to 6 are values relative to the respective Po values of Comparative Examples 1 to 6 assumed to be 1. In Table 1, the ΔVfs in Examples 1 to 6 are values obtained by subtracting the respective measured values of Vf in Comparative Examples 1 to 6 from the measured values of Vf in the experiments of Examples 1 to 6. A smaller ΔVf indicates that the device is less affected by a reduction of the contact area, which leads to excellent properties. As large relative value of Po indicates that light output power is more effectively improved, which leads to excellent properties. Note that the Po was measured with respect to the light extracted from the sapphire substrate side due to reflection in Example 5 in which the reflective electrode was formed, and in other examples, the Po was measured with respect to the light extracted from the p-type nitride semiconductor layer side, which layer having the openings.

TABLE 1

| | Aperture | | Po ratio | | | ΔVf | | |
|---|---|---|---|---|---|---|---|---|
| | ratio | | (INDEX) | | | (V) | | |
| | (%) | Reference | 20 mA | 50 mA | 100 mA | 20 mA | 50 mA | 100 mA |
| Example 1 | 30.3 | Comparative Example 1 | 1.62 | 1.54 | 1.52 | 0.09 | 0.17 | 0.18 |
| Example 2 | 38.3 | Comparative Example 2 | 2.51 | 2.43 | 2.39 | 0.04 | 0.03 | 0.02 |
| Example 3 | 20.0 | Comparative Example 3 | 1.25 | 1.21 | — | 0.13 | 0.19 | — |
| Example 4 | 20.0 | Comparative Example 4 | 1.38 | 1.38 | 1.38 | 0.04 | 0.04 | 0.08 |
| Example 5 | 30.3 | Comparative Example 5 | 1.33 | 1.27 | 1.28 | 0.09 | 0.17 | 0.18 |
| Example 6 | 38.3 | Comparative Example 6 | 1.14 | 1.13 | 1.12 | 0.05 | 0.08 | 0.13 |

### (Evaluation Result)

As compared to Comparative Examples 1 to 5, in Examples 1 to 5, the Po was roughly 1.3 times to two times or more higher but the Vf was only slightly higher. Accordingly, the light emission efficiency was significantly improved without substantially increasing the forward voltage. Further, a larger aperture ratio is likely to result in a higher output power improving effect.

Further, comparing Example 3 and Example 4 with the same aperture ratio, the Po was higher in Example 4 than in Example 3. This may also be attributed to the following factor. Since fine openings of 1 μm to 2 μm or less were not easily formed by photolithography due to limitations in the design of the photomask pattern width, the openings were larger in Example 3, whereas the openings in Example 4 each had a fine and complicated shape having a width of 2 μm or less to constitute a set of openings having non-uniform aperture shapes. Further, the ΔVf was found to be higher in Example 3 than in Example 4. This is considered because a current hardly flows in the center portion of each opening in Example 3 due to the distance from the contact portion, which makes Vf to easily increase. Moreover, the SEM micrographs show that the bottom surface of each opening was relatively flat in Example 3, whereas the bottom surface of each opening in Example 4 had more irregularities as compared with Example 3. Since the openings had a non-uniform shape, the etch rate varied in the opening surfaces, which resulted in the irregularities on the surfaces of the p-type nitride semiconductor layer in the openings. It is assumed that this also contributed to the improvement in the light output power.

Further, for the case of a blue light emitting diode in Example 6, the Po was effectively improved by approximately 14% as compared with Comparative Example 6. However, the improving effect was more significant in Examples 1 to 5. This is considered because the device has a longer emission wavelength as compared with the ultraviolet light emitting diode in Example 2 and it absorbs less light at the contact layer. Accordingly, the present invention was found to have significantly advantageous effects on light emitting devices in which the contact layer has a narrower band gap than the light emitting layer, and particularly on light emitting devices emitting ultraviolet light.

Even in the case where the reflective electrode was formed as in Example 5, the Po was effectively improved by approximately 30%, which proved the effect of the present invention. Note that the reasons that Example 5 showed a lower Po than in Example 1 are not clear due also to differences in the measurement conditions. One of the reasons may be that the reflectance of the reflective electrode was not 100% and the actual reflectance was lower.

Also in a case where ScN was used as a lift-off layer, Ru having high reflectivity with respect to ultraviolet light was formed as the p-type electrode on the entire surface, and a vertical semiconductor light emitting device joined to a conductive Si substrate was formed using AuSn as a joint metal, the similar effects were obtained.

### INDUSTRIAL APPLICABILITY

According to the present invention, openings are provided in a contact portion in which a contact layer and an ohmic electrode layer of a semiconductor light emitting device are stacked, which allows attempts to achieve both suppression of light absorption in the contact portion and a good ohmic contact between the electrode and a semiconductor layer. Thus, the light output power can be improved without significantly increasing forward voltage.

### REFERENCE SIGNS LIST

100: Semiconductor light emitting device
101: Substrate
102: Buffer layer
103: N-type semiconductor layer (Second conductivity type semiconductor layer)
104: Light emitting layer
105: P-type semiconductor layer (First conductivity type semiconductor layer)
106: Semiconductor laminate
107: Contact layer
108: Ohmic electrode layer
109: Contact portion
110: Mask
111: Opening
112: N-side electrode (Second electrode)
113: P-side electrode (First electrode)
114: Bump

1. A semiconductor light emitting device comprising:
a semiconductor laminate including a first conductivity type semiconductor layer, a light emitting layer, and a second conductivity type semiconductor layer having a conductivity type different from the first conductivity type, in this order;
a contact portion in which a contact layer and an ohmic electrode layer are stacked on the first conductivity type semiconductor layer;
a plurality of island-like openings provided in the contact portion, in which openings the first conductivity type semiconductor layer is exposed;
a first electrode which is in contact with the ohmic electrode layer and is electrically connected to the first conductivity type semiconductor layer; and
a second electrode electrically connected to the second conductivity type semiconductor layer.

2. The semiconductor light emitting device according to claim 1, wherein the shape of the plurality of the openings viewed from above the device is non-uniform.

3. The semiconductor light emitting device according to claim 1, wherein the band gap of the contact layer is narrower than the band gap of the light emitting layer.

4. The semiconductor light emitting device according to claim 3, wherein the semiconductor laminate is made of a III-nitride semiconductor, and the contact layer is made of AlₓGa₁₋ₓN (0≦x<0.5).

5. The semiconductor light emitting device according to claim 1, wherein the light emitting layer emits ultraviolet light.

6. The semiconductor light emitting device according to claim 1, wherein the first conductivity type semiconductor layer is a p-type semiconductor layer.

7. A method of manufacturing a semiconductor light emitting device, comprising the steps of:
forming a semiconductor laminate including a second conductivity type semiconductor layer, a light emitting layer, and a first conductivity type semiconductor layer having a conductivity type different from the second conductivity type, in this order, on a substrate;
forming a contact portion in which a contact layer and an ohmic electrode layer are stacked on the first conductivity type semiconductor layer;
forming a mask on part of the contact portion;
removing part of the contact portion which is exposed without being provided with the mask by etching, thereby forming a plurality of island-like openings in the contact portion such that the first conductivity type semiconductor layer is exposed;
forming a first electrode which is in contact with the ohmic electrode layer and is electrically connected to the first conductivity type semiconductor layer; and
forming a second electrode electrically connected to the second conductivity type semiconductor layer.

8. The method of manufacturing a semiconductor light emitting device, according to claim 7, wherein the shape of the plurality of the openings viewed from above the device is non-uniform.

9. The method of manufacturing a semiconductor light emitting device, according to claim 7, wherein the step of forming the mask comprises the steps of:
forming an aluminum oxide film on the contact portion by aluminum deposition in an oxygen atmosphere; and
partially etching the aluminum oxide film.

10. The method of manufacturing a semiconductor light emitting device, according to claim 7 wherein the light emitting layer emits ultraviolet light.
